(19) United States
(12) Patent Application Publication
(10) Pub. No.: US 2012/0031471 A1
(43) Pub. Date: Feb. 9, 2012

(54) SOLAR PANEL MODULE

(75) Inventors: Szu-Han LI, Taoyuan County (TW); Yi-Ling Chen, Taichung City (TW); Ching-Yee Chak, Hong Kong (HK); Wing-Yan Lai, Hong Kong (HK); Hung-Ming Tseng, Taipei City (TW)

(73) Assignee: Du Pont Apollo Limited, Hong Kong (HK)

(21) Appl. No.: 13/193,611

(22) Filed: Jul. 29, 2011

Related U.S. Application Data
(60) Provisional application No. 61/371,749, filed on Aug. 9, 2010.

(51) Int. Cl. H01L 31/048

(52) U.S. Cl. 136/251

(57) ABSTRACT

A solar panel module includes a solar panel, a generally rectangular frame, a pair of bridge members and a beam. The solar panel has a light-receiving surface and a back surface on two opposite sides thereof. The generally rectangular frame is attached to all edges of the solar panel. The pair of bridge members are secured to a pair of parallel edges of the generally rectangular frame on the back surface of the solar panel. The beam is interconnected between the pair of bridge members, wherein each bridge member has a wider width than a width of the beam.

### RELATED APPLICATIONS

This application claims priority to U.S. Provisional Application Ser. No. 61/371,749, filed Aug. 9, 2010, which is herein incorporated by reference.

### BACKGROUND

1. Field of Invention

The present invention relates to a solar panel module.

2. Description of Related Art

Extensive research effort is presently being expended to develop mass production capabilities for photovoltaic cells generating electrical energy from incident solar radiation. As used herein, a photovoltaic or solar panel refers to an array of photovoltaic cells, which may comprise silicon materials or polycrystalline thin films in a common glass substrate and connected in series or parallel configurations. The resulting solar panels are fragile and should desirably be provided with a frame or other support in an overall power producing network.

Since the solar panels are most mounted on a roof surface of a building, some solar panels may be designed to be stronger to endure violent weather conditions in some areas. In some areas, such as southeastern coasts of China, violent winds occur in summer days, i.e. a typhoon. There is a need for improving the solar panel module to meet such weather conditions when the solar panel module is used in these areas.

### SUMMARY

It is therefore an objective of the present invention to provide a stronger solar panel module to endure violent external forces.

In accordance with the foregoing and other objectives of the present invention, a solar panel module includes a solar panel, a generally rectangular frame, a pair of bridge members and a beam. The solar panel has a light-receiving surface and a back surface on two opposite sides thereof. The generally rectangular frame are attached to all edges of the solar panel. The pair of bridge members are secured to a pair of parallel edges of the generally rectangular frame on the back surface of the solar panel. The beam is interconnected between the pair of bridge members, wherein each bridge member has a wider width than a width of the beam.

In an embodiment disclosed herein, the width of each bridge member is at least three times wider than the width of the beam.

In another embodiment disclosed herein, a bonding tape is disposed between the beam and the back surface.

In another embodiment disclosed herein, a bonding tape is disposed between each bridge member and the back surface.

In another embodiment disclosed herein, a bolt is used to fasten an end portion of the beam to each bridge member.

In another embodiment disclosed herein, the pair of parallel edges are a longer pair of parallel edges of the generally rectangular frame.

In another embodiment disclosed herein, the beam is perpendicular to the pair of parallel edges of the generally rectangular frame.

In another embodiment disclosed herein, a junction box is disposed on the back surface of the solar panel, and there is a gap between said junction box and said beam.

In accordance with the foregoing and other objectives of the present invention, a solar panel module includes a solar panel, a generally rectangular frame, multiple pairs of bridge members and multiple beams. The solar panel has a light-receiving surface and a back surface on two opposite sides thereof. The generally rectangular frame is attached to all edges of the solar panel. Multiple pairs of bridge members are secured to a pair of parallel edges of the generally rectangular frame on the back surface of the solar panel. Each of multiple beams is interconnected between the corresponding pair of bridge members, wherein each bridge member has a wider width, which is at least three times wider than a width of the beam.

In an embodiment disclosed herein, a bonding tape is disposed between each beam and the back surface.

In another embodiment disclosed herein, a bonding tape is disposed between each bridge member and the back surface.

In another embodiment disclosed herein, a bolt is used to fasten an end portion of the beam to each bridge member.

In another embodiment disclosed herein, the pair of parallel edges are a longer pair of parallel edges of the generally rectangular frame.

In another embodiment disclosed herein, the beam is perpendicular to the pair of parallel edges of the generally rectangular frame.

In another embodiment disclosed herein, a junction box is disposed on the back surface of the solar panel, and there is a gap between said junction box and said beam.

Thus, an improved solar panel module is equipped with strength-enhancing members attached to a bottom side thereof so as to enhance its capability against violent external forces.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a bottom view of a solar panel module according to one preferred embodiment of this invention;

FIG. 2 illustrates an exploded view of strength-enhancing members attached to a bottom side of the solar panel module as illustrated in FIG. 1;

FIG. 3 illustrates an enlarged view of two major components of the strength-enhancing members according to one preferred embodiment of this invention; and

FIG. 4 illustrates a cross-sectional view along the cross-sectional line 4-4′ in FIG. 1.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

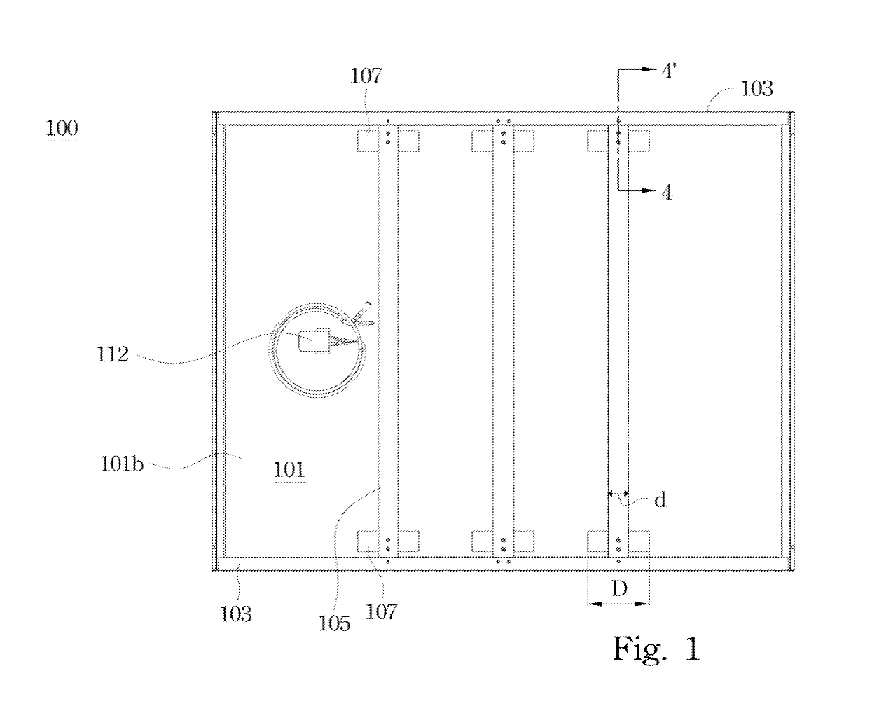

FIG. 1 illustrates a bottom view of a solar panel module according to one preferred embodiment of this invention. In order to make a stronger solar panel module 100, strength-enhancing members are installed on a back surface 101b of a solar panel 101. A set of strength-enhancing member at least includes a pair of bridge members 107 and a beam 105 interconnected between the pair of bridge members 107. Multiple sets of strength-enhancing members can be installed on the back surface 101b of a solar panel, e.g. three sets of strength-enhancing members as illustrated in FIG. 1, to enhance its ability to against violent external forces, such as violent winds. Because a junction box 112 is also installed on the back surface 101b of a solar panel 101, the strength-enhancing member should be installed without interfering the junction box 112 and its output power cables. To be specific, there is a gap between the junction box 112 and the strength-enhancing member, i.e. the beam 105.

In order to uniformly distribute stresses that the frame 103 applies upon the solar panel 101, each bridge member 107 is made with a wider width D than a width d of each beam 105. Preferably, the width D of each bridge member 107 is at least three times wider than the width d of each beam 105 to prevent a damaging stress upon the fragile solar panel.

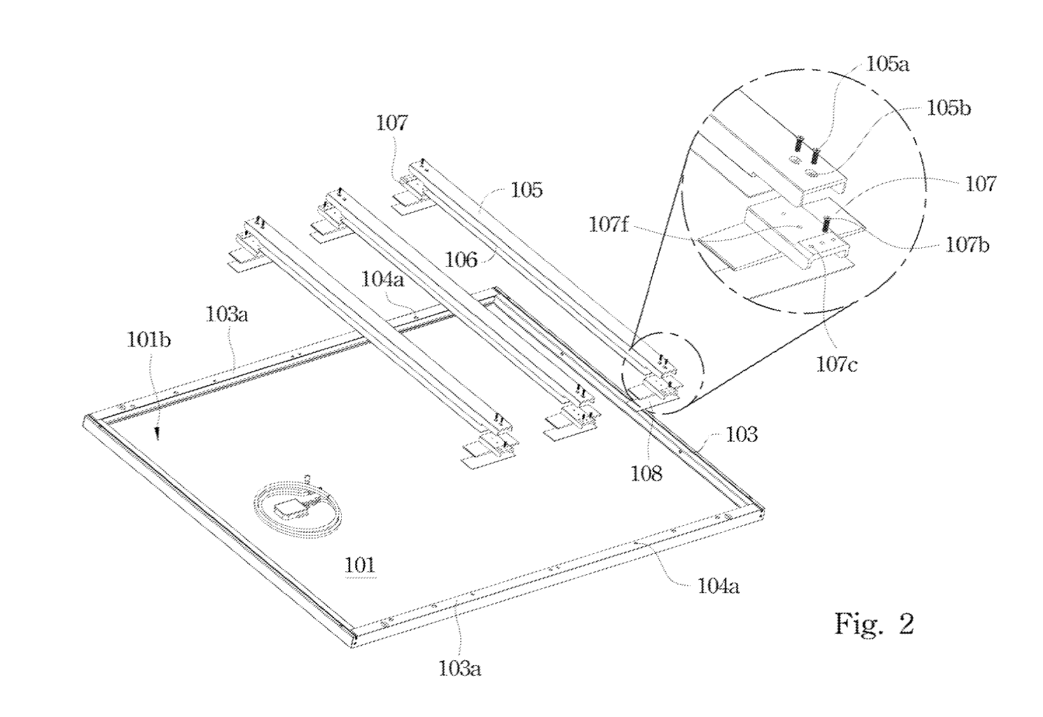

FIG. 2 illustrates an exploded view of strength-enhancing members attached to a bottom side of the solar panel module as illustrated in FIG. 1. In this embodiment, the strength-enhancing members are fastened to a frame 103, i.e. a generally rectangular frame, by means of bolts. In an alternate embodiment, the strength-enhancing members can be fastened to the frame 103 by other methods, such as welding. The frame 103 surrounds and secures all edges of the solar panel 101.

Each pair of bridge members 107 are fastened to a pair of parallel edges 103a of the frame 103, e.g. a longer pair of parallel edges, by means of bolts. Each bridge member 107 is fastened to each corresponding edge 103a by using a bolt 107b inserted through a through hole 104a and screwed into a threaded hole 107c. An end portion of each beam 105 is fastened to each pair of bridge members 107 by using a bolt 105a inserted through a through hole 105b and screwed into a threaded hole 107f.

In this embodiment, the beam 105 is a beam with a C-shaped cross-section. In an alternate embodiment, the beam can be equipped with other types of cross-sections, e.g. an I-shaped cross-section (not illustrated in the drawings).

In order to enhance an effective support for the solar panel 101, each bridge members 107 and each beam 105 are in contact with the back surface 101b of the solar panel 101. In this embodiment, a bonding tape 108 is used to attach the bridge member 107 to the back surface 101b of the solar panel 101 while a bonding tape 106 is used to attach the beam 105 to the back surface 101b of the solar panel 101.

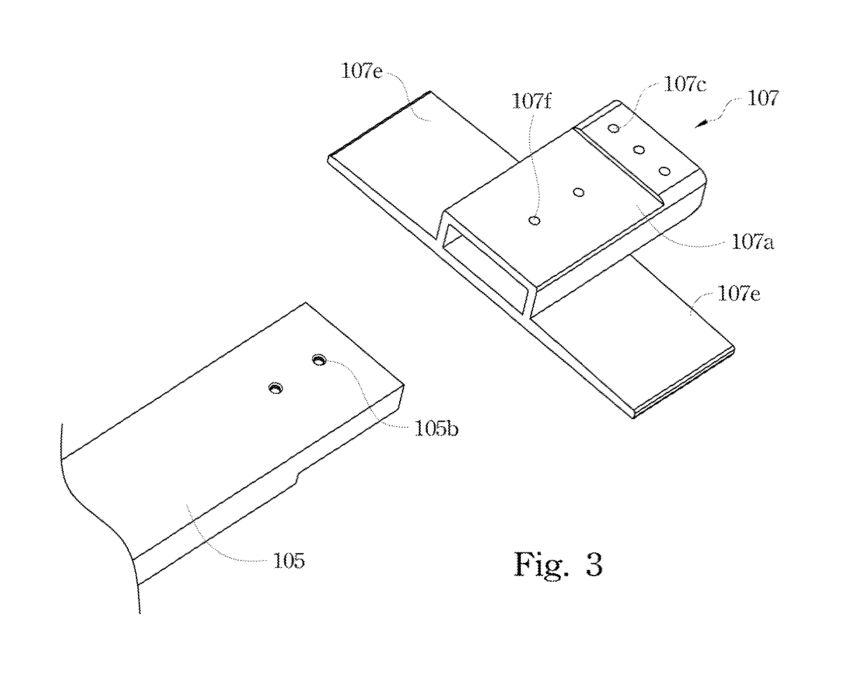

FIG. 3 illustrates an enlarged view of two major components of the strength enhancing members according to one preferred embodiment of this invention. The bridge member 107 basically includes a main portion 107a and a pair of wings 107e extending from the main portion 107a. The pair of wings 107e are made thinner to be lighter (compared with the main portion 107a) to expand a width of the bridge member 107. The beam 105 (with C-shaped cross-section) are installed to house three surfaces of the main portion 107a (i.e., a top and two side surfaces) and fastened to the main portion 107a by means of bolts, e.g. using two bolts inserted through two through holes 105b and screwed into two threaded holes 107f, respectively.

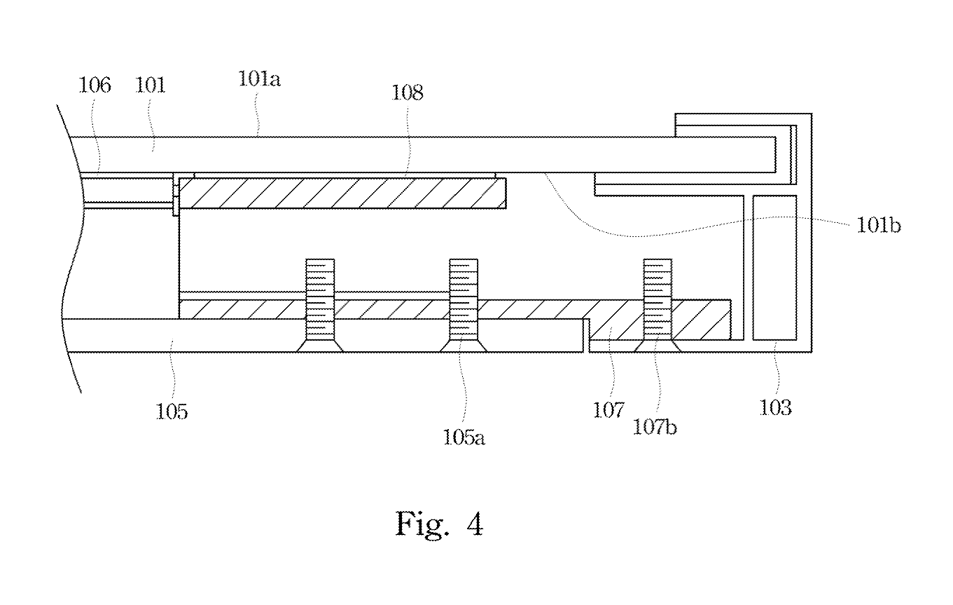

FIG. 4 illustrates a cross-sectional view along the cross-sectional line 4-4′ in FIG. 1. This cross-sectional view illustrates assembly details of the solar panel module. In particular, the bridge member 107 is fastened to the frame 103 by means of the bolt 107b while the beam 105 is fastened to the bridge member 107 by means of the bolts 105a. In addition, the bonding tape 108 is arranged between the bridge member 107 and the back surface 101b of the solar panel 101 while the bonding tape 106 is arranged between the beam 105 and the back surface 101b of the solar panel 101. The solar panel 101 has a light-receiving surface 101 a and the back surface 101b on its two opposite sides. The light-receiving surface 101a is to collect solar radiation.

According to above-discussed embodiments, an improved solar panel module is equipped with strength-enhancing members (e.g. a bridge member and a beam) attached to a bottom side thereof so as to enhance its capability against violent external forces.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar panel module comprising:
a solar panel having a light-receiving surface and a back surface on two opposite sides thereof; and
a generally rectangular frame attached to all edges of the solar panel;
a pair of bridge members secured to a pair of parallel edges of the generally rectangular frame on the back surface of the solar panel; and
a beam interconnected between the pair of bridge members, wherein each bridge member has a wider width than a width of the beam.

2. The solar panel module of claim 1, wherein the width of each bridge member is at least three times wider than the width of the beam.

3. The solar panel module of claim 1, further comprising a bonding tape disposed between each bridge member and the back surface.

4. The solar panel module of claim 1, further comprising a bonding tape disposed between the beam and the back surface.

5. The solar panel module of claim 1 further comprising a bolt to fasten an end portion of the beam to each bridge member.

6. The solar panel module of claim 1, wherein the pair of parallel edges are a longer pair of parallel edges of the generally rectangular frame.

7. The solar panel module of claim 1, wherein the beam is perpendicular to the pair of parallel edges of the generally rectangular frame.

8. The solar panel module of claim 1 further comprising a junction box disposed on the back surface of the solar panel, and there is a gap between said junction box and said beam.

9. The solar panel module of claim 1 further comprising a bolt to fasten the pair of bridge members to the pair of parallel edges of the generally rectangular frame.

10. A solar panel module comprising:
a solar panel having a light-receiving surface and a back surface on two opposite sides thereof; and
a generally rectangular frame attached to all edges of the solar panel;
multiple pairs of bridge members secured to a pair of parallel edges of the generally rectangular frame on the back surface of the solar panel; and
multiple beams each interconnected between the corresponding pair of bridge members, wherein each bridge member has a wider width, which is at least three times wider than a width of the beam.

11. The solar panel module of claim 10, further comprising a bonding tape disposed between each bridge member and the back surface.

12. The solar panel module of claim 10, further comprising a bonding tape disposed between each beam and the back surface.

13. The solar panel module of claim 10 further comprising a bolt to fasten an end portion of each beam to each bridge member.

14. The solar panel module of claim 10, wherein the pair of parallel edges are a longer pair of parallel edges of the generally rectangular frame.

15. The solar panel module of claim 10, wherein each beam is perpendicular to the pair of parallel edges of the generally rectangular frame.

16. The solar panel module of claim 10 further comprising a junction box disposed on the back surface of the solar panel, and there is a gap between said junction box and said beam.

17. The solar panel module of claim 10 further comprising a bolt to fasten each pair of bridge members to the pair of parallel edges of the generally rectangular frame.
